(19) United States
(12) Patent Application Publication
(10) Pub. No.: US 2026/0173695 A1
(43) Pub. Date: Jun. 18, 2026

(54) Display Device and Vehicle Comprising Thereof

(71) Applicant: LG Display Co., Ltd., Seoul (KR)

(72) Inventors: JongHyun Park, Paju-si (KR); Minho Lee, Paju-si (KR)

(21) Appl. No.: 19/097,517

(22) Filed: Apr. 1, 2025

(30) Foreign Application Priority Data
Dec. 18, 2024 (KR) 10-2024-0190260

(51) Int. Cl. H10K 59/35; B60K 35/22; H10K 59/80

(52) U.S. Cl. CPC H10K 59/353; H10K 59/351; H10K 59/352; H10K 59/873; H10K 59/879; B60K 35/22; B60K 2360/1523

(57) ABSTRACT

A display device and a vehicle comprising thereof enhance viewing angle luminance by constituting one subpixel with a plurality of division pixels. The display device comprises: a substrate on which a main division pixel and at least one subdivision pixel adjacent to the main division pixel are disposed; and a lens unit disposed on the main division pixel and the at least one subdivision pixel, and including a main lens corresponding to the main division pixel and at least one sub lens respectively corresponding to the at least one subdivision pixel, wherein a central axis of each of the at least one sub division pixel does not overlap a central axis of the at least one sub lens respectively corresponding to the at least one subdivision pixel.

### CROSS-REFERENCE TO RELATED APPLICATION

This application claims priority from Republic of Korea Patent Application No. 10-2024-0190260, filed on Dec. 18, 2024, which is hereby incorporated by reference in its entirety.

### BACKGROUND

### Field

Embodiments of the disclosure relate to a display device.

### Description of Related Art

The growth of information society leads to various needs for displays and wide use of various forms of displays, such as liquid crystal displays (LCDs) or organic light emitting diode displays (OLEDs).

These display devices are applied in various forms to various product groups, such as televisions (TVs), monitors, laptop computers, smartphones, tablets, electronic pads, wearable devices, smart watches, portable information devices, navigation, and vehicle displays.

In particular, the panel size of display devices mounted in vehicles is gradually increasing with technological advancements and user demands, and efforts are being made to enhance display quality in line with the increasing panel size.

### SUMMARY

Embodiments of the disclosure may provide a display device capable of enhancing viewing angle brightness by dividing a single subpixel into a plurality of division pixels.

Embodiments of the disclosure may provide a display device capable of enhancing viewing angle brightness and reducing power consumption by optimizing a plurality of division pixels and the positions of lenses respectively corresponding to the division pixels.

Embodiments of the disclosure may provide a display device capable of enhancing viewing angle brightness and light extraction efficiency at the same time by optimizing the shape of the pixel electrode where a plurality of division pixels are disposed.

Objects of embodiments of the disclosure are not limited to those set forth herein, and other unmentioned objects would be apparent to one of ordinary skill in the art from the following description.

Embodiments of the disclosure may provide a display device comprising a substrate on which a main division pixel and at least one subdivision pixel adjacent to the main division pixel are disposed, and a lens unit disposed on the main division pixel and the at least one sub division pixel, and including a main lens corresponding to the main division pixel and at least one sub lens respectively corresponding to the at least one sub division pixel.

Embodiments of the disclosure may provide a display device comprising a display panel where a plurality of subpixels each having a main division pixel and at least one sub division pixel adjacent to the main division pixel, a plurality of gate lines, a plurality of data lines, and at least one sub lens positioned on the at least one sub division pixel are disposed, a data driving circuit supplying a data voltage to the plurality of data lines, and a gate driving circuit driving the plurality of gate lines.

Embodiments of the disclosure may provide a vehicle comprising the display device as above.

The central axis of each of the at least one subdivision pixel may not overlap the central axis of at least one sub lens respectively corresponding to the at least one subdivision pixel.

According to embodiments of the disclosure, there may be provided a display device capable of enhancing viewing angle brightness by dividing a single subpixel into a plurality of division pixels.

According to embodiments of the disclosure, there may be provided a display device capable of enhancing viewing angle brightness and reducing power consumption by optimizing a plurality of division pixels and the positions of lenses respectively corresponding to the division pixels.

According to embodiments of the disclosure, there may be provided a display device capable of enhancing viewing angle brightness and light extraction efficiency at the same time by optimizing the shape of the pixel electrode where a plurality of division pixels are disposed.

The effects of the disclosure are not limited to the foregoing effects, and other effects will be apparent to one of ordinary skill in the art from the following detailed description.

### BRIEF DESCRIPTION OF DRAWINGS

The disclosure will be more fully understood from the following detailed description and the accompanying drawings, which are provided for illustration only and are not intended to limit the disclosure.

FIG. 1 is a view illustrating a display device according to embodiments of the disclosure;

FIG. 2 is a view illustrating an application example of a display device according to embodiments of the disclosure;

FIG. 3 is a view illustrating an example of a subpixel according to embodiments of the disclosure;

FIGS. 4 to 6 are views illustrating a display panel according to embodiments of the disclosure;

FIG. 7 is a view illustrating an implementation example of a display panel according to embodiments of the disclosure; and

FIG. 8 is a view illustrating an implementation example of a pixel electrode according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

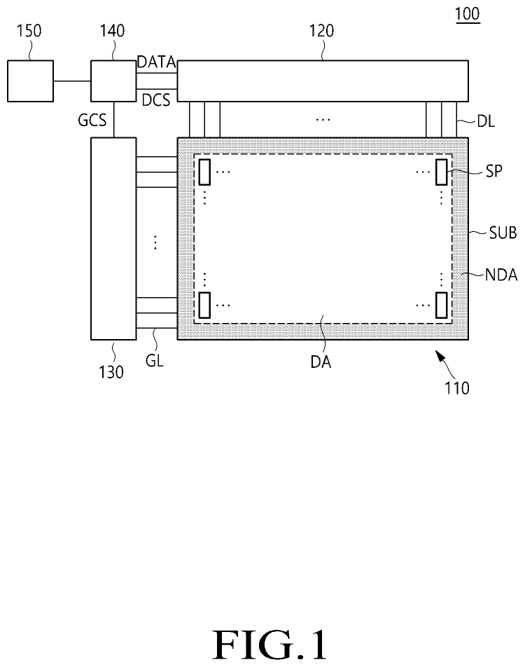

FIG. 1 is a view illustrating a display device 100 according to embodiments of the disclosure.

Referring to FIG. 1, according to embodiments of the disclosure, a display device 100 may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The display panel 110 may include a plurality of subpixels SP connected to the plurality of data lines DL and the plurality of gate lines GL.

The display panel 110 may include a display area DA in which images are displayed and a non-display area NDA which is positioned outside of the display area DA and where no image is displayed. In the display panel 110, a plurality of subpixels SP for displaying images may be disposed in the display area DA, and the driving circuits 120, 130, and 140 may be electrically connected or disposed in the non-display area NDA. Further, pad units for connection of integrated circuits or a printed circuit may be disposed in the non-display area NA.

Each of the plurality of subpixels SP according to embodiments of the disclosure may include a main division pixel and at least one subdivision pixel adjacent to the main division pixel.

The data driving circuit 120 is a circuit for driving the plurality of data lines DL and may supply data signals to the plurality of data lines DL. The gate driving circuit 130 is a circuit for driving the plurality of gate lines GL, and may supply gate signals to the plurality of gate lines GL.

The gate driving circuit 130 may include at least one scan driver supplying gate signals to a plurality of gate lines GL and at least one emission control driver.

For example, the gate driving circuit 130 may include at least one first scan driver supplying a first scan gate signal, which is a type of gate signal, at least one second scan driver supplying a second scan gate signal, which is a type of gate signal, and at least one emission control driver supplying an emission control gate signal, which is a type of gate signal.

According to an embodiment, the gate driving circuit 130 may include a plurality of stages respectively corresponding to the plurality of gate lines GL, and each of the plurality of stages may include at least one scan driver and at least one emission control driver.

The controller 140 may supply a data control signal DCS to the data driving circuit 120 to control the operation timing of the data driving circuit 120. The controller 140 may supply a gate control signal GCS for controlling the operation timing of the gate driving circuit 130 to the gate driving circuit 130.

The controller 140 may control to start a scan operation according to a timing implemented in each frame, convert input image data input from the outside (e.g., the host system 150) into image data DATA suited for the data signal format used in the data driving circuit 120, supply the image data DATA to the data driving circuit 120, and control data driving to proceed at an appropriate time according to the scan timing.

Specifically, the controller 140 may receive various timing signals, including a vertical synchronization signal VSYNC, a horizontal synchronization signal HSYNC, a data enable signal DE, and a clock signal CLK, along with the input image data, and generate various control signals DCS and GCS to control the data driving circuit 120 and the gate driving circuit 130 and output them to the data driving circuit 120 and the gate driving circuit 130.

The controller 140 may be implemented as a separate component from the data driving circuit 120, or the controller 140, along with the data driving circuit 120, may be implemented as an integrated circuit.

The data driving circuit 120 may receive the image data DATA from the controller 140 and supply data voltages to the plurality of data lines DL, thereby driving the plurality of data lines DL. Here, the data driving circuit 120 may be described as a source driving circuit.

The data driving circuit 120 may include one or more source driver integrated circuit SDIC.

For example, each source driver integrated circuit (SDIC) may be connected with the display panel 110 by a tape automated bonding (TAB) type or connected to a bonding pad of the display panel 110 by a chip on glass (COG) or chip on panel (COP) type or may be implemented by a chip on film (COF) type and connected with the display panel 110.

The gate driving circuit 130 may output a gate signal of a turn-on voltage level or a gate signal of a turn-off voltage level according to the control of the controller 140. The gate driving circuit 130 may sequentially drive the plurality of gate lines GL by sequentially supplying gate signals of the turn-on voltage level to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

The gate driving circuit 130 may be composed of a plurality of stages, and when the gate driving circuit 130 is implemented in a gate-in-panel GIP type, each of the plurality of stages may be implemented as a plurality of GIP circuits.

At least one of the data driving circuit 120 and the gate driving circuit 130 may be disposed in the display area DA. For example, at least one of the data driving circuit 120 and the gate driving circuit 130 may be disposed not to overlap a plurality of subpixels SP or to overlap all or some of the plurality of subpixels SP.

When a specific gate line GL is opened by the gate driving circuit 130, the data driving circuit 120 may convert the image data DATA received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The display device 100 according to embodiments of the disclosure may be a display including a backlight unit, such as a liquid crystal display, or may be a self-emission display, such as an organic light emitting diode (OLED) display, a quantum dot display, or a micro light emitting diode (LED) display.

According to an embodiment of the disclosure, when the display device 100 is an OLED display, each subpixel SP may include an organic light emitting diode (OLED), which is self-luminous, as a light emitting element. According to an embodiment of the disclosure, when the display device 100 is a quantum dot display, each subpixel SP may include a light emitting element formed of a quantum dot, which is a self-luminous semiconductor crystal. If the display device 100 according to embodiments of the disclosure is a micro LED display, each subpixel SP may include a micro LED, which is self-emissive and formed of an inorganic material, as the light emitting element.

The display panel 110 according to embodiments of the disclosure may have a top emission structure or a bottom emission structure, and in some cases, may have a double-side emission structure.

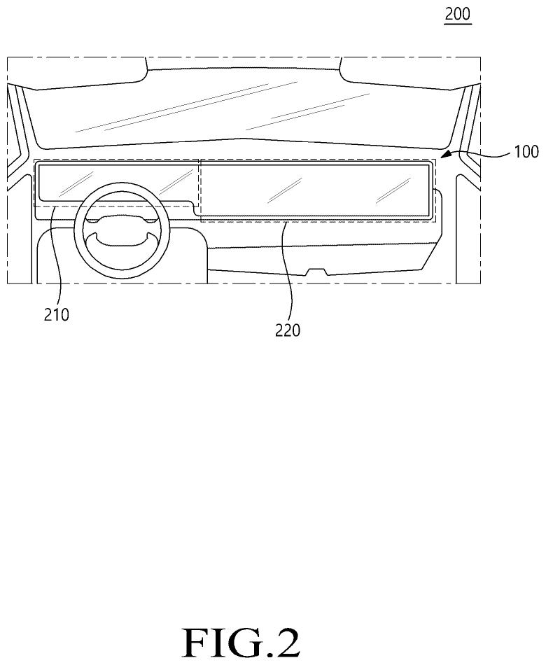

FIG. 2 is a view illustrating an application example of a display device 100 according to embodiments of the disclosure.

Referring to FIG. 2, the display device 100 according to embodiments of the disclosure may be disposed in the vehicle 200. However, embodiments of the disclosure are not limited thereto, and the display device 100 may be applied in various forms to various product groups such as TVs, monitors, notebook computers, smartphones, tablets, electronic pads, wearable devices, smart watches, and portable information devices.

Specifically, the display device 100 may be disposed on at least a portion of the dashboard of the vehicle 200, and the dashboard of the vehicle 200 may be disposed in front of the front seat (e.g., driver's seat or passenger seat) of the vehicle 200.

For example, the dashboard of the vehicle 200 may include components for controlling various functions (e.g., air conditioner, audio system, or navigation system) inside the vehicle 200.

The display device 100 may be disposed on the dashboard of the vehicle 200 to operate as an input unit for manipulating at least some of the above-described functions of the vehicle 200. The display device 100 may provide various information related to the vehicle 200, e.g., driving information about the vehicle (e.g., current speed of the vehicle, remaining fuel amount, driving distance), and information about components of the vehicle (e.g., damage to vehicle tires).

According to an embodiment, the display device 100 may be disposed to cross the driver's seat and the passenger seat disposed in the front seats of the vehicle 200. For example, as illustrated in FIG. 2, the display device 100 may be disposed to extend horizontally from the driver's seat where the steering wheel is disposed to the passenger seat. The display device 100 may include a first area 210 disposed adjacent to the driver's seat and a second area 220 disposed adjacent to the passenger seat.

According to an embodiment, an image (i.e., content) different from that of the second area 220 may be displayed in the first area 210.

Various contents for driving may be displayed in the first area 210. For example, in the first area 210, at least one of the current speed, the driving distance, the vehicle state and the remaining amount of fuel, and the current status of the vehicle indication lamps may be displayed.

Various types of content including entertainment content may be displayed in the second area 220. For example, in the second area 220, at least one of a vehicle environment control button, game content, video content, and messenger content may be displayed.

According to an embodiment, the sizes of the first area 210 and the second area 220 may be different from each other.

For example, the size of the first area 210 may be smaller than the size of the second area 220. Specifically, the first area 210 may have an area corresponding to the driver's seat, and the second area 220 may be disposed to have an area corresponding to an area other than the driver's seat, such as a shared area between the passenger seat and the driver's seat. Further, the height (or vertical length) of the first area 210 may be shorter than the height of the second area 220, and the width (or horizontal length) of the first area 210 may be shorter than the width of the second area 220. However, embodiments of the disclosure are not limited thereto.

Meanwhile, when the display device 100 is implemented as a large-sized display positioned in front of the driver's seat and passenger seat, as in the example of FIG. 2, a decrease in luminance may occur due to the difference in distance from each of the driver's seat and passenger seat to the display device 100, resulting in viewing restrictions on the video displayed on the display device 100.

Specifically, in the driver's seat, viewing restrictions may occur on the image displayed in the second area 220 due to decreases in viewing angle luminance due to the distance as compared with the original video of the video displayed in the second area 220, and in the passenger seat, viewing restrictions may occur on the video displayed in the first area 210 due to decreases in viewing angle luminance due to the distance as compared with the original video of the video displayed in the first area 210.

Accordingly, the display device 100 according to embodiments of the disclosure may divide each subpixel SP disposed in the display panel 110 into a plurality of division pixels (e.g., a main division pixel, and a sub division pixel), and optimally arrange the plurality of division pixels to minimize or at least reduce the occurrence of a decrease in left/right viewing angle luminance of the display device 100, thereby mitigating the viewing restrictions on the video output through the display device 100.

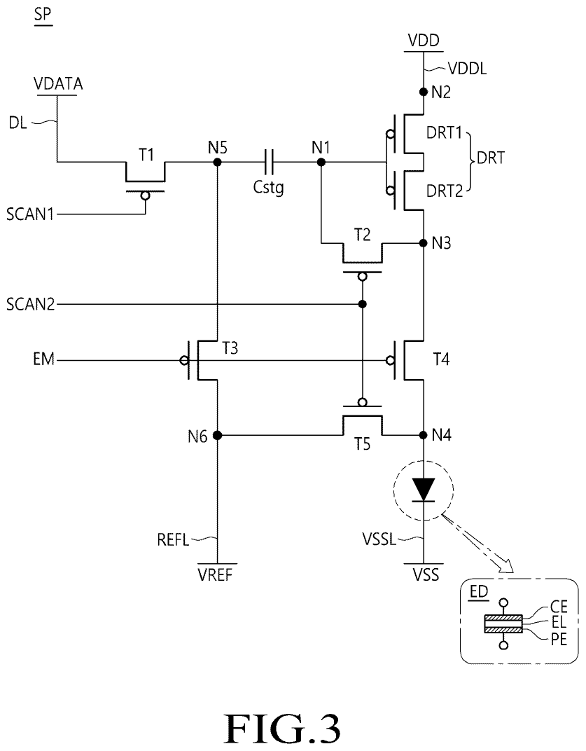

FIG. 3 is a view illustrating an example of a subpixel SP according to embodiments of the disclosure.

Referring to FIG. 3, the subpixel SP may include a light emitting element ED and a driving transistor DRT configured to drive the light emitting element ED.

The light emitting element ED may include a pixel electrode PE and a common electrode CE and may further include a light emitting layer EL positioned between the pixel electrode PE and the common electrode CE.

The pixel electrode PE of the light emitting element ED may be an electrode disposed in each subpixel SP and the common electrode CE may be an electrode commonly disposed in all the subpixels SP.

For example, the pixel electrode PE may be an anode electrode and the common electrode CE may be a cathode electrode. Conversely, the pixel electrode PE may be a cathode electrode, and the common electrode CE may be an anode electrode.

The pixel electrode PE of the light emitting element ED may be connected to the fourth node N4, and the common electrode CE may be connected to the low-potential voltage line VSSL supplying the low-potential voltage VSS.

For example, the light emitting element ED may be at least one of an organic light emitting diode (OLED), a light emitting diode (LED), and a quantum dot light emitting element.

The subpixel SP may further include one or more transistors other than the driving transistor DRT. According to the example of FIG. 3, the subpixel SP may further include first to fifth transistors T1 to T5.

According to the example of FIG. 3, the driving transistor DRT may include a first driving transistor DRT1 and a second driving transistor DRT2.

The driving transistor DRT may include a first node N1, a second node N2, and a third node N3. Here, the first node N1 may be a gate node of the first driving transistor DRT1 and the second driving transistor DRT2, the second node N2 may be a source or drain node of the first driving transistor DRT1, and the third node N3 may be a drain or source node of the second driving transistor DRT2.

The drain or source node of the first driving transistor DRT1 may be connected to the source or drain node of the second driving transistor DRT2, and the first driving transistor DRT1 may be connected to the high-potential voltage line VDDL supplying the high-potential voltage VDD through the second node N2.

The first transistor T1 may receive a first scan gate signal SCAN1 of the turn-on voltage level from the gate driving circuit 130 to control the connection between the data line DL supplying the data voltage VDATA and the fifth node N5.

The first scan gate signal SCAN1 of the turn-on voltage level may be a signal of a high voltage level when the first transistor T1 is an n-type transistor, and a signal of a low voltage level when the first transistor T1 is a p-type transistor.

The second transistor T2 may receive the second scan gate signal SCAN2 of the turn-on voltage level from the gate driving circuit 130 to control the connection between the first node N1 and the third node N3.

The fifth transistor T5 may receive a second scan gate signal SCAN2 of the turn-on voltage level from the gate driving circuit 130 to control the connection between the fourth node N4 and the sixth node N6.

The fifth transistor T5 is connected to a reference voltage line REFL for applying a reference voltage VREF through the sixth node N6 and may supply the reference voltage VREF to the fourth node N4 during the turn-on operation.

The second scan gate signal SCAN2 of the turn-on voltage level may be a signal of a high voltage level when the second transistor T2 and the fifth transistor T5 are n-type transistors and may be a signal of a low voltage level when the second transistor T2 and the fifth transistor T5 are p-type transistors.

The third transistor T3 may receive a light emission control gate signal EM of the turn-on voltage level from the gate driving circuit 130 to control the connection between the fifth node N5 and the sixth node N6.

The fourth transistor T4 may receive a light emission control gate signal EM of the turn-on voltage level from the gate driving circuit 130 to control the connection between the third node N3 and the fourth node N4.

The light emission control gate signal EM of the turn-on voltage level may be a signal of a high voltage level when the third and fourth transistors T3 and T4 are n-type transistors and may be a signal of a low voltage level when the third and fourth transistors T3 and T4 are p-type transistors.

The subpixel SP may further include a storage capacitor Cstg disposed between the first node N1 and the fifth node N5 to maintain a predetermined voltage during one frame.

According to the example of FIG. 3, the first driving transistor DRT1, the second driving transistor DRT2, and the first to fifth transistors T1 to T5 may be p-type transistors. However, embodiments of the disclosure are not limited thereto, and at least one of the first driving transistor DRT1, the second driving transistor DRT2, and the first to fifth transistors T1 to T5 may be designed as an n-type transistor.

The first driving transistor DRT1, the second driving transistor DRT2, and the first to fifth transistors T1 to T5 may be low-temperature polycrystalline silicon (LTPS) transistors. However, embodiments of the disclosure are not limited thereto, and at least one of the first driving transistor DRT1, the second driving transistor DRT2, and the first to fifth transistors T1 to T5 may be designed as an oxide transistor.

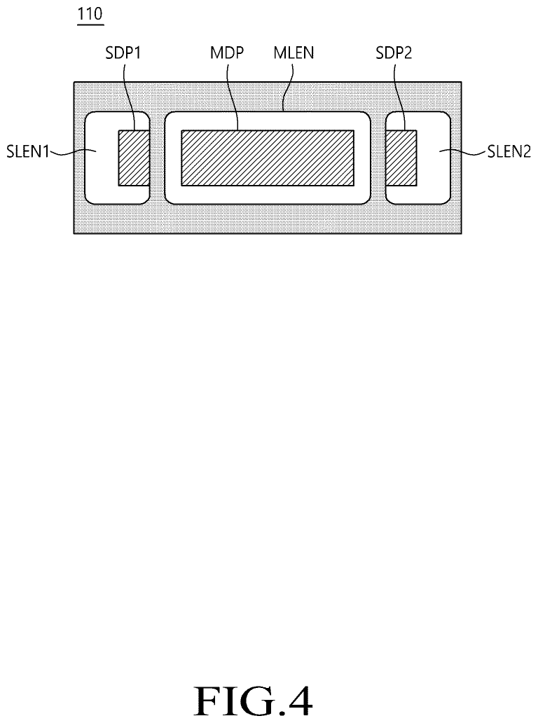

FIGS. 4 to 6 are views illustrating a display panel 110 according to embodiments of the disclosure.

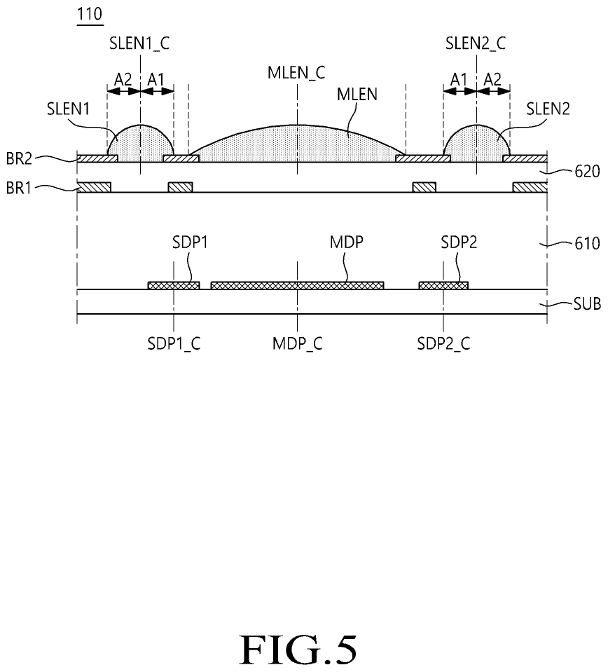

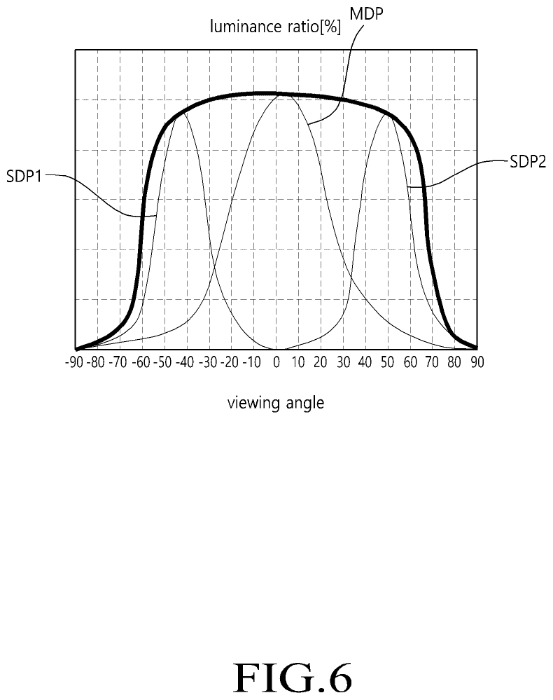

Specifically, FIG. 4 is a plan view according to an example of the display panel 110 according to embodiments of the disclosure, FIG. 5 is a cross-sectional view according to an example of the display panel 110 according to embodiments of the disclosure, and FIG. 6 is a view illustrating viewing angle luminance characteristics of a display panel 110 according to embodiments of the disclosure.

Referring to FIGS. 4 and 5, a display panel 110 according to embodiments of the disclosure may include a substrate SUB on which a main division pixel MDP and at least one subdivision pixel adjacent to the main division pixel MDP are disposed, and a lens unit disposed on the main division pixel MDP and the at least one subdivision pixel.

The main division pixel MDP and at least one subdivision pixel may constitute one subpixel SP that outputs light of the same color, and the size of each of the at least one subdivision pixel may be designed to be smaller than the size of the main division pixel MDP.

For example, the plurality of subpixels SP may include at least one first-color (e.g., red) subpixel, at least one second-color (e.g., green) subpixel, and at least one third-color (e.g., blue) subpixel. The first-color subpixel may include a first-color main division pixel and at least one first-color subdivision pixel, the second-color subpixel may include a second-color main division pixel and at least one second-color sub division pixel, and the third-color subpixel may include a third-color main division pixel and at least one third-color sub division pixel.

According to an embodiment, the plurality of subpixels SP may further fourth-color (e.g., white) subpixel, and the fourth-color subpixel may include a fourth-color main division pixel and at least one fourth-color sub division pixel.

According to the examples of FIGS. 4 and 5, at least one subdivision pixel may include a first subdivision pixel SDP1 disposed to be spaced apart from a first side surface of the main division pixel MDP by a preset distance, and a second subdivision pixel SDP2 disposed to be spaced apart from a second side surface of the main division pixel by a preset distance, but embodiments of the disclosure are not limited thereto, and three or more sub division pixels may be disposed in one subpixel SP.

The lens unit may include a main lens MLEN corresponding to the main division pixel MDP and at least one sub lens respectively corresponding to the at least one subdivision pixel, and the size of each of the at least one sub lens may be smaller than the size of the main lens MLEN.

For example, when at least one subdivision pixel is the first subdivision pixel SDP1 and the second subdivision pixel SDP2, the lens unit may include a first sub lens SLEN1 corresponding to the first subdivision pixel SDP1 and a second sub lens SLEN2 corresponding to the second subdivision pixel SDP2.

The central axis MDP_C of the main division pixel MDP and the central axis MLEN_C of the main lens MLEN may be designed to overlap each other, but embodiments of the disclosure are not limited thereto.

The central axis of each of the at least one subdivision pixel may be designed not to overlap the central axis of at least one sub lens respectively corresponding to the at least one subdivision pixel.

Specifically, the central axis SDP1_C of the first subdivision pixel SDP1 and the central axis SLEN1_C of the first sub lens SLEN1 may be designed not to overlap each other, and the central axis SDP2_C of the second subdivision pixel SDP2 and the central axis SLEN2_C of the second sub lens SLEN2 may be designed not to overlap each other.

According to the example of FIG. 5, the first sub lens SLEN1 may include a first area A1 adjacent to the main lens MLEN and a second area A2 which is an area other than the first area A1 with respect to the central axis SLEN1_C of the first sub lens SLEN1, at least a portion of the first area A1 of the first sub lens SLEN1 may overlap at least a portion of the first sub division pixel SDP1, and the second area A2 of the first sub lens SLEN1 may not overlap the first sub lens SLEN1.

Further, the second sub lens SLEN2 may include a first area A1 adjacent to the main lens MLEN and a second area A2, which is an area other than the first area A1, with respect to the central axis SLEN2_C of the second sub lens SLEN2, at least a portion of the first area A1 of the second sub lens SLEN2 may overlap at least a portion of the second sub division pixel SDP2, and the second area A2 of the second sub lens SLEN2 may not overlap the second sub lens SLEN2.

In other words, the central axis SDP1_C of the first sub division pixel SDP1 may be positioned between the central axis SLEN1_C of the first sub lens SLEN1 and the central axis MLEN_C of the main lens MLEN, and the central axis SDP2_C of the second sub division pixel SDP2 may be positioned between the central axis SLEN2_C of the second sub lens SLEN2 and the central axis MLEN_C of the main lens MLEN.

Accordingly, light output from the first subdivision pixel SDP1 may be diffused in a first direction (left direction with respect to FIG. 5) of the display panel 110 through the first sub lens SLEN1_C, and light output from the second subdivision pixel SDP2 may be diffused in a second direction (right direction with respect to FIG. 5) of the display panel 110 through the second sub lens SLEN2_C.

Accordingly, as illustrated in FIG. 6, the display device 100 may minimize a decrease in viewing angle luminance according to a viewing position based on light output from each of the main division pixel MDP, the first subdivision pixel SDP1, and the second subdivision pixel SDP2.

According to the example of FIG. 5, the display panel 110 may further include an encapsulation layer 610 disposed on the substrate SUB to cover the main division pixel MDP, the first sub division pixel SDP1, and the second sub division pixel SDP2, a plurality of first barriers BR1 disposed on the encapsulation layer 610, an upper interlayer insulation layer 620 disposed on the encapsulation layer 610 to cover the plurality of first barriers BR1, and a plurality of second barriers BR2 disposed on the upper interlayer insulation layer 620.

Although FIG. 5 illustrates that the encapsulation layer 610 is disposed in an area between the first subdivision pixel SDP1 and the main division pixel MDP2 and an area between the main division pixel MDP and the second subdivision pixel SDP2, embodiments of the disclosure are not limited thereto, and an encapsulation layer 610 may be disposed on the common electrode CE of the main division pixel MDP1, the first subdivision pixel SDP1, and the second subdivision pixel SDP2.

The plurality of first barriers BR1 may include a resin material, and the plurality of second barriers BR2 may include a metal material, but embodiments of the disclosure are not limited thereto.

The respective sizes of the plurality of first barriers BR1 may be the same, but embodiments of the disclosure are not limited thereto, and at least two barriers among the plurality of first barriers BR1 may be designed to have different sizes.

Likewise, each of the plurality of second barriers BR2 may have the same size, but embodiments of the disclosure are not limited thereto, and at least two of the plurality of second barriers BR2 may be designed to have different sizes.

The size of each of the plurality of first barriers BR1 may be smaller than the size of each of the plurality of second barriers BR2 or may be the same as the size of each of the plurality of second barriers BR2.

The upper interlayer insulation layer 620 includes a plurality of emission areas where a plurality of second barriers BR2 are not formed, and the main lens MLEN, the first sub lens SLEN1, and the second sub lens SLEN2 may be disposed in a corresponding emission area among the plurality of emission areas on the upper interlayer insulation layer 620.

In other words, the plurality of emission areas where the plurality of second barriers BR2 are not formed on the upper interlayer insulation layer 620 may mean an area where light output from each of the main division pixel MDP, the first subdivision pixel SDP1, and the second subdivision pixel SDP2 is transferred to each of the main lens MLEN, the first sub lens SLEN1, and the second sub lens SLEN2.

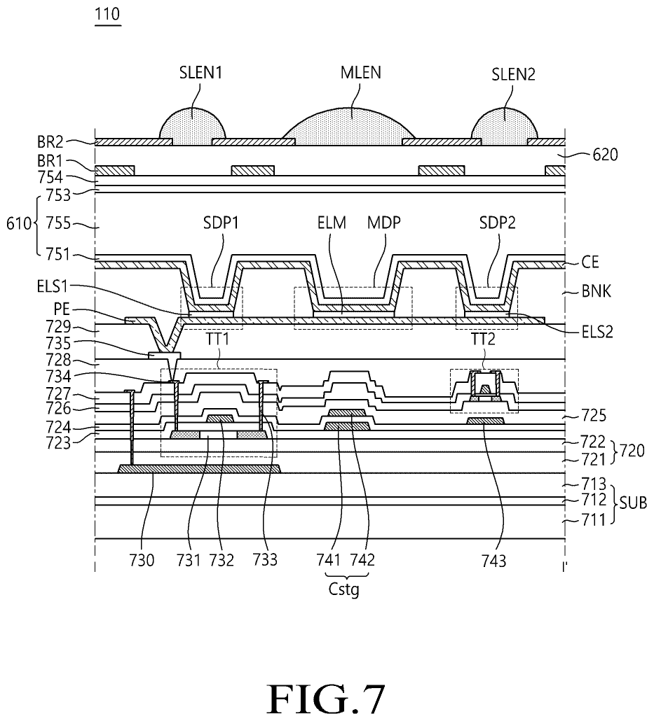

FIG. 7 is a view illustrating an embodiment of a display panel 110 according to embodiments of the disclosure.

Referring to FIG. 7, a display panel 110 according to embodiments of the disclosure may include a substrate SUB, a plurality of insulation films disposed on the substrate SUB, at least one transistor disposed between the plurality of insulation films, a plurality of division pixels MDP, SDP1, and SDP2 disposed on the plurality of insulation films, an encapsulation layer 610 disposed on the plurality of division pixels MDP, SDP1, and SDP2, a plurality of first barriers BR1 disposed on the encapsulation layer 610, an upper interlayer insulation layer 620 disposed on the encapsulation layer 610 to cover the plurality of first barriers BR1, a plurality of second barriers BR2 disposed on the upper interlayer insulation layer 620, and a plurality of lenses MLEN, SLEN1, and SLEN2 disposed on the upper interlayer insulation layer 620 and disposed at positions respectively corresponding to a plurality of emission areas where the plurality of second barriers BR2 are not disposed on the upper interlayer insulation layer 620.

According to the example of FIG. 7, the plurality of division pixels MDP, SDP1, and SDP2 may include a main division pixel MDP, a first subdivision pixel SPD1, and a second subdivision pixel SDP2, and the plurality of lenses MLEN, SLEN1, and SLEN2 may include a main lens MLEN, a first sub lens SLEN1, and a second sub lens SLEN2.

According to the example of FIG. 7, the main division pixel MDP, the first subdivision pixel SPD1, and the second subdivision pixel SDP2 may constitute one subpixel SP and share the same pixel electrode PE.

The substrate SUB may include a first substrate 711 and a second substrate 713 and may further include an intermediate layer 712 disposed between the first substrate 711 and the second substrate 713. For example, the intermediate layer 712 may be an inorganic layer that blocks moisture penetration.

The plurality of insulation films may include a first buffer layer 720, a first gate insulation layer 723, a first interlayer insulation layer 724, a second buffer layer 725, a second gate insulation layer 726, a second interlayer insulation layer 727, a third interlayer insulation layer 728, and a first planarization layer 729, which are sequentially disposed on the substrate SUB.

The first buffer layer 720 may be a single film or multiple films. When the first buffer layer 720 is multiple films, the first buffer layer 720 may include a multi-buffer layer 721 and an active buffer layer 722.

A first light blocking layer 730 may be disposed between the first buffer layer 720 and the substrate SUB. The first light blocking layer 730 may serve as a light shield that blocks light introduced from a lower portion.

Various transistors TT1 and TT2 and a storage capacitor Cstg in the subpixel SP may be disposed on the first buffer layer 720.

A first-type transistor TT1 may be disposed on the first buffer layer 720, and here, the first-type transistor TT1 may be at least one transistor provided in the subpixel SP. For example, the first-type transistor TT1 may include at least one of the fourth transistor T4 and the fifth transistor T5 in the subpixel SP.

The first-type transistor TT1 may include a first active layer 731, a first electrode 733, a second electrode 734, and a first gate electrode 732.

For example, the first electrode 733 may be one of the source electrode and the drain electrode of the first-type transistor TT1, and the second electrode 734 may be the other of the source electrode and the drain electrode of the first-type transistor TT1.

The first active layer 731 may be disposed on the first buffer layer 720 and may fully or partially overlap the first light blocking layer 730.

The first active layer 731 may include a first channel area overlapping the first gate electrode 732, a first connection area positioned on one side of the first channel area and contacting the first electrode 733, and a second connection area positioned on the other side of the first channel area and contacting the second electrode 733.

The first gate insulation layer 723 may be disposed on the first active layer 731, the first gate electrode 732 may be disposed on the first gate insulation layer 723, the first interlayer insulation layer 724 may be disposed on the first gate insulation layer 723 to cover the first gate electrode 732, and the second buffer layer 725 may be disposed on the first interlayer insulation layer 724.

The second light blocking layer 743 may be disposed between the first interlayer insulation layer 724 and the second buffer layer 725, and the second light blocking layer 743 may play the same role as the first light blocking layer 730.

The first electrode 733 and the second electrode 734 of the first-type transistor TT1 may be disposed on the second interlayer insulation layer 727.

Specifically, the first electrode 733 and the second electrode 734 of the first-type transistor TT1 may be connected to the first connection area and the second connection area, respectively, of the first active layer 731 through through-holes penetrating the second interlayer insulation layer 727, the second gate insulation layer 726, the second buffer layer 725, the first interlayer insulation layer 724, and the first gate insulation layer 723, respectively.

A second-type transistor TT2 may be disposed on the second buffer layer 725, and here, the second-type transistor TT2 may be a transistor provided in the subpixel SP.

Specifically, the second-type transistor TT2 may include a second active layer, a third electrode, a fourth electrode, and a second gate electrode.

For example, the third electrode may be one of the source electrode and the drain electrode of the second-type transistor TT2, and the fourth electrode may be the other of the source electrode and the drain electrode of the second-type transistor TT2.

The second active layer may be disposed on the second buffer layer 725 and may fully or partially overlap the second light blocking layer 743.

The second active layer may include a second channel area overlapping the second gate electrode, a third connection area positioned on one side of the second channel area and contacting the third electrode, and a fourth connection area positioned on the other side of the second channel area and contacting the fourth electrode.

The second gate insulation layer 726 may be disposed on the second active layer, the second gate electrode may be disposed on the second gate insulation layer 726, and the second interlayer insulation layer 727 may be disposed on the second gate insulation layer 726 to cover the second gate electrode.

The third and fourth electrodes of the second-type transistor TT2 may be disposed on the second interlayer insulation layer 727.

Specifically, the third and fourth electrodes of the first-type transistor TT1 may be connected to the third and fourth connection areas, respectively, of the second active layer through through-holes penetrating the second interlayer insulation layer 727, the second gate insulation layer 726, and the second buffer layer 725, respectively.

According to an embodiment, the display panel 110 according to embodiments of the disclosure may not include the second light blocking layer 743 and the second-type transistor TT2 when all of the transistors (e.g., DRT1, DRT2, and T1 to T5) in the subpixel SP are LTPS transistors.

Further, the display panel 110 according to embodiments of the disclosure may not include at least one of the second buffer layer 725 and the second gate insulation layer 726 when all of the transistors (e.g., DRT1, DRT2, and T1 to T5) in the subpixel SP are LTPS transistors.

The storage capacitor Cstg in the subpixel SP may include a first capacitor electrode 741 and a second capacitor electrode 742. A first interlayer insulation layer 724 may be disposed between the first capacitor electrode 741 and the second capacitor electrode 742.

A third interlayer insulation layer 728 may be disposed on the second interlayer insulation layer 727. In other words, the third interlayer insulation layer 728 may be disposed on the first electrode 733 and the second electrode 734 of the first-type transistor TT1, and on the third and fourth electrodes of the second-type transistor TT2.

A connection electrode 735 may be disposed on the third interlayer insulation layer 728, and here, the connection electrode 735 may be an electrode that relays an electrical connection between the second electrode 734 of the first-type transistor TT1 and the pixel electrode PE.

The connection electrode 735 may be electrically connected to the second electrode 734 of the first-type transistor TT1 through the through-hole penetrating the third interlayer insulation layer 728.

A first planarization layer 729 may be disposed on the third interlayer insulation layer 728 to cover the connection electrode 735.

According to an embodiment, the first planarization layer 729 may be implemented in a single-layer structure or a multi-layer structure of at least two layers.

A pixel electrode PE electrically connected to the connection electrode 735 may be disposed on the first planarization layer 729.

The pixel electrode PE may include an opaque conductive material capable of reflecting light. For example, the pixel electrode PE may include any one of metals such as aluminum (Al), gold (Au), silver (Ag), copper (Cu), tungsten (W), molybdenum (Mo), chromium (Cr), tantalum (Ta), titanium (Ti), or alloys thereof, but embodiments of the disclosure are not limited thereto.

A bank layer BNK may be disposed on the pixel electrode PE and the first planarization layer 729, and the bank layer BNK may include a plurality of bank holes exposing the upper surface of the pixel electrode PE. In other words, each of the plurality of bank holes may overlap a portion of the pixel electrode PE.

The light emitting layer ELM of the main division pixel MDP, the light emitting layer ELS1 of the first subdivision pixel SPD1, and the light emitting layer ELS2 of the second subdivision pixel SPD2 may be disposed on the pixel electrode PE to correspond to each of the plurality of bank holes.

A common electrode CE may be disposed on the light emitting layers ELM, ELS1, and ELS2 and the bank layer BNK. The common electrode CE may include a transparent electrode material.

An encapsulation layer 610 may be disposed on the common electrode CE, and the encapsulation layer 610 may include a first encapsulation layer 751, a second encapsulation layer 755 on the first encapsulation layer 751, and a third encapsulation layer 753 on the second encapsulation layer 752.

For example, the first encapsulation layer 751 and the third encapsulation layer 753 may include at least one of silicon nitride (SiNx), silicon oxide (SiOx), or aluminum oxide (AlyOz), and the second encapsulation layer may include an organic material, but embodiments of the disclosure are not limited thereto.

The second encapsulation layer 755 may cover against foreign substances or particles that may occur during a manufacturing process. Further, the second encapsulation layer 755 may planarize the surface of the first encapsulation layer 751.

According to an embodiment, layers for providing a touch function may be disposed on the encapsulation layer 610.

According to an embodiment, a third buffer layer 754 may be disposed on the encapsulation layer 610, and a plurality of first barriers BR1 may be disposed on the third buffer layer 754.

For example, the first barrier BR1 may include at least one of black pigment, black resin, graphite, black ink, gravure ink, black spray, and black enamel. When the first barrier BR1 is formed of the above-described materials, it may absorb at least 80% of visible light.

The plurality of first barriers BR1 may be disposed to be spaced apart from each other, and the spaced area of the plurality of first barriers BR1 may correspond to an emission path of the light output from each of the main division pixel MDP, the first subdivision pixel SPD1, and the second subdivision pixel SDP2.

The upper interlayer insulation layer 620 may be disposed on the third buffer layer 754 to cover the plurality of first barriers BR1, and a plurality of second barriers BR2 may be disposed on the upper interlayer insulation layer 620.

The upper interlayer insulation layer 620 includes a plurality of emission areas where a plurality of second barriers BR2 are not formed, and the main lens MLEN, the first sub lens SLEN1, and the second sub lens SLEN2 may be disposed in a corresponding emission area among the plurality of emission areas on the upper interlayer insulation layer 620.

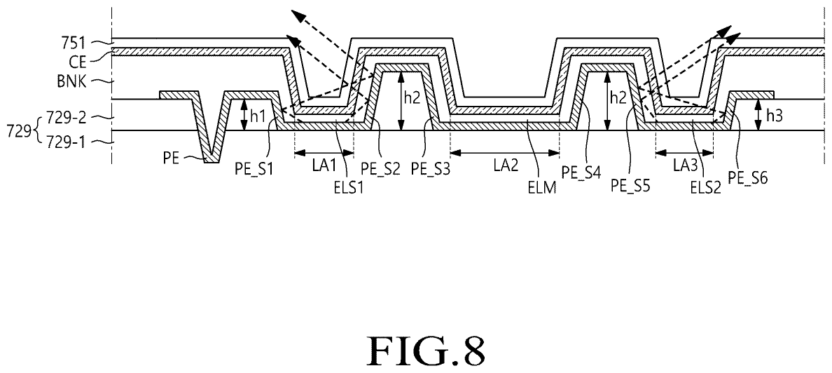

FIG. 8 is a view illustrating an implementation example of a pixel electrode PE according to embodiments of the disclosure.

Referring to FIG. 8, a subpixel SP according to embodiments of the disclosure may include a main division pixel MDP, a first subdivision pixel SDP1, and a second subdivision pixel SDP2, and the main division pixel MDP1, the first subdivision pixel SDP1, and the second subdivision pixel SDP2 may share the same pixel electrode PE.

The pixel electrode PE may be disposed on the first planarization layer 729, and according to embodiments, the first planarization layer 729 may include a 1-1th planarization layer 729-1 and a 1-2th planarization layer 729-2 disposed on the 1-1th planarization layer 729-1.

According to the example of FIG. 8, the pixel electrode PE may include a first disposition area LA1 formed between a first inclined portion PE_S1 having a first step h1 and a second inclined portion PE_S2 having a second step h2, a second disposition area LA2 formed between a third inclined portion PE_S3 having the second step h2 and a fourth inclined portion PE_S4 having the second step h2, and a third disposition area LA3 formed between a fifth inclined portion PE_S5 having the second step h2 and a sixth inclined portion PE_S6 having a third step h3.

The first step h1, the second step h2, and the third step h3 may refer to height differences from the respective highest points of the inclined portions PE_S1, PE_S2, PE_S3, PE_S4, PE_S5, and PE_S6 to the upper surface of the 1-1th planarization layer 729-1.

The light emitting layer ELS1 of the first subdivision pixel SDP1 may be disposed in the first disposition area LA1 of the pixel electrode PE, the light emitting layer ELM of the main division pixel MDP may be disposed in the second disposition area LA2 of the pixel electrode PE, and the light emitting layer ELS2 of the second subdivision pixel SDP2 may be disposed in the third disposition area LA3 of the pixel electrode PE.

As illustrated in FIG. 8, the size of the first step h1 and the size of the third step h3 may be smaller than the size of the second step h2.

In other words, in the display device 100 according to embodiments of the disclosure, the first step h1 of the pixel electrode PE is designed to be smaller than the second step h2, so that not only the light output directly from the light emitting layer ELS1 of the first sub division pixel SDP1 but also the light output in the directions of the first inclined portion PE_S1 and the second inclined portion PE_S2 may be reflected in the direction of the first sub lens SLEN1, thereby enhancing light extraction efficiency.

Likewise, in the display device 100 according to embodiments of the disclosure, the third step h3 of the pixel electrode PE is designed to be smaller than the second step h2, so that not only the light output directly from the light emitting layer ELS2 of the second sub division pixel SDP2 but also the light output in the directions of the fifth inclined portion PE_S5 and the sixth inclined portion PE_S6 may be reflected in the direction of the second sub lens SLEN2, thereby enhancing light extraction efficiency.

According to the example of FIG. 8, the size of the first step h1 may be the same as the size of the third step h3, but embodiments of the disclosure are not limited thereto, and the size of the first step h1 and the size of the third step h3 may be designed to be different from each other.

A display device according to an embodiment of the disclosure may be described as follows.

A display device according to embodiments of the disclosure may comprise a substrate on which a main division pixel and at least one subdivision pixel adjacent to the main division pixel are disposed, and a lens unit disposed on the main division pixel and the at least one subdivision pixel, and including a main lens corresponding to the main division pixel and at least one sub lens respectively corresponding to the at least one sub division pixel. A central axis of each of the at least one subdivision pixel may not overlap a central axis of the at least one sub lens respectively corresponding to the at least one subdivision pixel.

The at least one sub lens may include a first area adjacent to the main lens and a second area that may be a remaining area other than the first area, with respect to the central axis of the at least one sub lens. At least a portion of the first area may overlap at least a portion of the at least one subdivision pixel, and the second area may not overlap the at least one subdivision pixel.

A size of each of the at least one subdivision pixel may be smaller than a size of the main division pixel.

The main division pixel and the at least one subdivision pixel may output light of the same color.

The display device may further comprise an encapsulation layer disposed on the substrate to cover the main division pixel and the at least one subdivision pixel, a plurality of first barriers disposed on the encapsulation layer, an upper interlayer insulation layer disposed on the encapsulation layer to cover the plurality of first barriers, and a plurality of second barriers disposed on the upper interlayer insulation layer.

The upper interlayer insulation layer may include a plurality of emission areas where the plurality of second barriers may be not formed.

The lens unit may have the main lens and the at least one sub lens disposed in each corresponding emission area among the plurality of emission areas on the upper interlayer insulation layer.

A size of each of the plurality of first barriers may be smaller than or equal to a size of each of the plurality of second barriers.

A central axis of the main division pixel and a central axis of the main lens may overlap each other.

The at least one subdivision pixel may include a first sub division pixel disposed to be spaced apart from a first side surface of the main division pixel by a preset distance, and a second sub division pixel disposed to be spaced apart from a second side surface opposite to the first side surface of the main division pixel by a preset distance.

The at least one sub lens may include a first sub lens disposed to at least partially overlap the first subdivision pixel and a second sub lens disposed to at least partially overlap the first subdivision pixel.

The main division pixel, the first subdivision pixel, and the second subdivision pixel may share the same pixel electrode.

The pixel electrode may include a first disposition area formed between a first inclined portion having a first step and a second inclined portion having a second step, and where a light emitting layer of the first sub division pixel may be disposed, a second disposition area formed between a third inclined portion having the second step and a fourth inclined portion having the second step, and where a light emitting layer of the main division pixel may be disposed, and a third disposition area formed between a fifth inclined portion having the second step and a sixth inclined portion having a third step, and where a light emitting layer of the second sub division pixel may be disposed.

Each of a size of the first step and a size of the third step may be smaller than a size of the second step.

The size of the first step and the size of the third step may be the same.

A size of each of the at least one sub lens may be smaller than a size of the main lens.

A display device according to embodiments of the disclosure may comprise a display panel where a plurality of subpixels each having a main division pixel and at least one sub division pixel adjacent to the main division pixel, a plurality of gate lines, a plurality of data lines, and at least one sub lens positioned on the at least one sub division pixel may be disposed, a data driving circuit supplying a data voltage to the plurality of data lines, and a gate driving circuit driving the plurality of gate lines. A central axis of each of the at least one subdivision pixel may not overlap a central axis of the at least one sub lens respectively corresponding to the at least one subdivision pixel.

A vehicle according to embodiments of the disclosure may comprise the display device as above.

The above description has been presented to enable any person skilled in the art to make and use the technical idea of the disclosure and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate on which a main division pixel and at least one subdivision pixel are disposed, the at least one subdivision pixel adjacent to the main division pixel; and
a lens unit on the main division pixel and the at least one subdivision pixel, the lens unit including a main lens corresponding to the main division pixel and at least one sub lens respectively corresponding to the at least one subdivision pixel,
wherein a central axis of each of the at least one subdivision pixel is non-overlapping with a central axis of the at least one sub lens respectively corresponding to the at least one subdivision pixel.

2. The display device of claim 1, wherein the at least one sub lens includes a first area adjacent to the main lens and a second area that is a remaining area other than the first area, with respect to the central axis of the at least one sub lens, and
wherein at least a portion of the first area overlaps at least a portion of the at least one subdivision pixel, and the second area is non-overlapping with the at least one subdivision pixel.

3. The display device of claim 1, wherein a size of each of the at least one subdivision pixel is smaller than a size of the main division pixel.

4. The display device of claim 1, wherein the main division pixel and the at least one subdivision pixel output light of a same color.

5. The display device of claim 1, further comprising:
an encapsulation layer on the substrate, the encapsulation layer covering the main division pixel and the at least one subdivision pixel;
a plurality of first barriers on the encapsulation layer;
an upper interlayer insulation layer on the encapsulation layer, the upper interlayer insulation layer covering the plurality of first barriers; and
a plurality of second barriers on the upper interlayer insulation layer.

6. The display device of claim 5, wherein the upper interlayer insulation layer includes a plurality of emission areas where the plurality of second barriers are not formed, and
wherein the lens unit has the main lens and the at least one sub lens disposed in each corresponding emission area among the plurality of emission areas on the upper interlayer insulation layer.

7. The display device of claim 5, wherein a size of each of the plurality of first barriers is smaller than or equal to a size of each of the plurality of second barriers.

8. The display device of claim 1, wherein a central axis of the main division pixel and a central axis of the main lens overlap each other.

9. The display device of claim 1, wherein the at least one subdivision pixel includes a first subdivision pixel that is spaced apart from a first side surface of the main division pixel by a preset distance and a second subdivision pixel spaced apart from a second side surface that is opposite to the first side surface of the main division pixel by a preset distance.

10. The display device of claim 9, wherein the at least one sub lens includes a first sub lens that at least partially overlaps the first subdivision pixel and a second sub lens that at least partially overlaps the first subdivision pixel.

11. The display device of claim 9, wherein the main division pixel, the first subdivision pixel, and the second subdivision pixel share a same pixel electrode.

12. The display device of claim 11, wherein the pixel electrode includes:
a first disposition area between a first inclined portion having a first step and a second inclined portion having a second step, and where a light emitting layer of the first subdivision pixel is disposed;
a second disposition area between a third inclined portion having the second step and a fourth inclined portion having the second step, and where a light emitting layer of the main division pixel is disposed; and
a third disposition area between a fifth inclined portion having the second step and a sixth inclined portion having a third step, and where a light emitting layer of the second subdivision pixel is disposed.

13. The display device of claim 12, wherein each of a size of the first step and a size of the third step is smaller than a size of the second step.

14. The display device of claim 13, wherein the size of the first step and the size of the third step are a same.

15. The display device of claim 1, wherein a size of each of the at least one sub lens is smaller than a size of the main lens.

16. A display device, comprising:
a display panel including a plurality of subpixels each having a main division pixel and at least one subdivision pixel that is adjacent to the main division pixel, a plurality of gate lines, a plurality of data lines, and at least one sub lens positioned on the at least one subdivision pixel;
a data driving circuit configured to supply a data voltage to the plurality of data lines; and
a gate driving circuit configured to drive the plurality of gate lines,
wherein a central axis of each of the at least one subdivision pixel is non-overlapping with a central axis of the at least one sub lens respectively corresponding to the at least one subdivision pixel.

17. A vehicle comprising the display device of claim 1.
